(19) United States
(12) Patent Application Publication
(10) Pub. No.: US 2025/0081677 A1
(43) Pub. Date: Mar. 6, 2025

(54) FLIP-CHIP LIGHT-EMITTING ELEMENT AND LIGHT-EMITTING DEVICE

(71) Applicant: Tianjin Sanan Optoelectronics Co., Ltd., Tianjin (CN)

(72) Inventors: Zhiwei WU, Tianjin (CN); Yanyun WANG, Tianjin (CN); Weiping XIONG, Tianjin (CN); Huanshao KUO, Tianjin (CN); Yuren PENG, Tianjin (CN)

(73) Assignee: Tianjin Sanan Optoelectronics Co., Ltd., Tianjin (CN)

(21) Appl. No.: 18/776,233

(22) Filed: Jul. 17, 2024

(30) Foreign Application Priority Data
Aug. 31, 2023 (CN) 202311110079.9

(51) Int. Cl. H01L 33/38; H01L 33/22; H01L 33/40

(52) U.S. Cl. CPC H10H 20/8316; H10H 20/82; H10H 20/832

(57) ABSTRACT

Disclosed are a flip-chip light-emitting element and a light-emitting device. The flip-chip light-emitting element includes an epitaxial layer, a contact electrode, an insulating layer and a pad electrode. The epitaxial layer includes a first semiconductor layer, an active layer and a second semiconductor layer, and a contact electrode is formed on the surface of the epitaxial layer. An insulating layer is formed on the epitaxial layer, and covers the surface, the edge area and the sidewall of the epitaxial layer. A pad electrode is formed on the insulating layer and connected to the contact electrode, and the pad electrode at least covers part of the sidewall of the epitaxial layer. When the flip-chip light-emitting element of the present disclosure is solidified through solder paste, it is possible to prevent Sn and Ag from migrating and ascending into the active layer, thereby improving the reliability of the flip-chip light-emitting element.

### CROSS-REFERENCE TO RELATED APPLICATION

This application claims the priority benefit of China application serial no. 202311110079.9, filed on Aug. 31, 2023. The entirety of the above-mentioned patent application is hereby incorporated by reference herein and made a part of this specification.

### BACKGROUND

### Technical Field

The present disclosure relates to the technical field of semiconductor devices and devices, and specifically, to a flip-chip light-emitting element and a light-emitting device.

### Description of Related Art

To prevent the luminous efficiency from being affected by the electrodes occupying the light-emitting area in face-up light-emitting elements, a flip-chip structure is designed by chip designers. That is, the face-up light-emitting element is turned upside down so that the light excited by the light-emitting layer is emitted directly from the other side of the electrode (the substrate is eventually peeled off and the chip material is transparent). In the meantime, a structure that facilitates the packaging of light-emitting elements is designed for flip-chip light-emitting elements, thereby forming a flip-chip light-emitting device.

Flip-chip light-emitting element are different from the conventional metal wire bonding method and the post-ball-mounting process. In conventional face-up light-emitting devices, the electrical side of the chip faces upward and is connected to the substrate through metal wire bonding. Flip-chip light-emitting elements are connected to the substrate with the electrical side facing down.

The flip-chip light-emitting element is in contact with the solder paste through its own pad electrode, and is solidified through the reflow soldering process. However, the solder paste is likely to ascend and migrate during the reflow soldering process, and the solder paste normally contains Ag and Sn. When the chip is driven by an externally applied current, if the Ag and Sn in the solder paste migrate and ascend to the position of the active layer (light-emitting layer) of the epitaxial layer of the flip-chip light-emitting element, abnormality and leakage failure of the light-emitting element might occur, and the usage of light-emitting elements might be affected.

### SUMMARY

The purpose of the embodiments of the present disclosure is to provide a flip-chip light-emitting element and a light-emitting device that may prevent Sn and Ag that migrate and ascend during the solder paste solidification process from entering the active layer as much as possible.

In a first aspect, a flip-chip light-emitting element is provided, which at least includes an epitaxial layer, a contact electrode, an insulating layer and a pad electrode. The epitaxial layer includes a first semiconductor layer, an active layer and a second semiconductor layer stacked in sequence, and a contact electrode is formed on the surface of the epitaxial layer. An insulating layer is formed on the epitaxial layer, and at least covers the surface of the epitaxial layer, the edge area and the sidewall of the epitaxial layer. A pad electrode is formed on the insulating layer and connected to the contact electrode, and the pad electrode at least covers part of the sidewall of the epitaxial layer.

According to a second aspect of the present disclosure, a light-emitting device is also provided, which includes the flip-chip light-emitting element in the aforementioned solution.

Compared with the existing technology, the advantageous effects of the disclosure at least include:

In the flip-chip light-emitting element of the present disclosure, since the pad electrode at least covers part of the sidewall of the epitaxial layer, during the solder paste solidification process, even if Sn and Ag in the flip-chip light-emitting element migrate and ascend, they will first migrate and ascend along the sidewall of the pad electrode. With the blocking effect of the pad electrode at the sidewall and the limited height that Sn and Ag can reach through migration and ascending, it is difficult for migrated and ascended Sn and Ag to enter the active layer of the epitaxial layer. In this way, it is possible to reduce the possibility of leakage failure of flip-chip light-emitting elements and improve the reliability of flip-chip light-emitting elements.

Even if some Sn and Ag migrate and ascend beyond the height of the sidewall covered by the pad electrode, the height that Sn and Ag can reach is relatively low. Under the circumstances, the insulating layer may also serve a certain blocking effect to prevent migrated and ascended Sn and Ag from entering the active layer.

In the meantime, since the pad electrode at least covers part of the sidewall of the epitaxial layer, the contact area between the pad electrode and the solder paste is increased, thereby improving the solderability of the flip-chip light-emitting element.

### BRIEF DESCRIPTION OF THE DRAWINGS

In order to more clearly illustrate the technical solutions of the embodiments of the present disclosure, the drawings required to be used in the embodiments will be briefly introduced below. It should be understood that the following drawings only show some embodiments of the present disclosure and therefore should not be regarded as a limitation of the scope. For those of ordinary skill in the art, other relevant drawings can be obtained based on these drawings without exerting inventive efforts.

FIG. 1 is a 3D view of a microstructure of a flip-chip light-emitting element according to an embodiment of the present disclosure.

FIG. 2 is a top view of a microstructure of a flip-chip light-emitting element according to an embodiment of the present disclosure.

FIG. 3 is a schematic cross-sectional view taken along line M-M when the flip-chip light-emitting element in FIG. 2 has a bonding layer.

FIG. 4 is a schematic cross-sectional view taken along line M-M when the flip-chip light-emitting element in FIG. 2 has no bonding layer.

FIG. 5 is an enlarged view of the partial structure denoted by “A” in FIG. 3 according to an embodiment of the present disclosure.

FIG. 6 is an enlarged view of a partial structure denoted by “A” in FIG. 3 according to an embodiment of the present disclosure.

FIG. 7 is a schematic view of relative positions of a pad electrode and two mesas according to an embodiment of the present disclosure.

FIG. 8 is an enlarged view of a partial structure denoted by “B” in FIG. 3 according to an embodiment of the present disclosure.

FIG. 9 is an enlarged view of a partial structure denoted by “A” in FIG. 3 according to an embodiment of the present disclosure.

FIG. 10 is a cross-sectional microstructural view of the pad electrode and the sidewall of the epitaxial layer of a multi-layer structure according to an embodiment of the present disclosure.

FIG. 11 is another enlarged view of a partial structure denoted by “B” in FIG. 3 according to an embodiment of the present disclosure.

FIG. 12 is a structural view of a light-emitting device according to an embodiment of the present disclosure.

### DESCRIPTION OF THE EMBODIMENTS

In order to make the purpose, technical solutions and advantages of the embodiments of the present disclosure clearer, the technical solutions in the embodiments of the present disclosure will be clearly and completely described below in conjunction with the drawings in the embodiments of the present disclosure. Clearly, the described embodiments are part of the embodiments of this disclosure, but not all of them. The components of the embodiments of the present disclosure generally described and illustrated in the figures herein may be arranged and designed in a variety of different configurations.

Accordingly, the following detailed description of the embodiments of the present disclosure provided in the appended drawings is not intended to limit the scope of claims, but rather to merely represent selected embodiments of the disclosure. Based on the embodiments in this disclosure, all other embodiments obtained by those of ordinary skill in the art without inventive efforts fall within the scope to be protected by the present disclosure.

It should be noted that, as long as there is no conflict, the technical solutions and technical features in the following embodiments may be used in combination.

### Embodiment 1

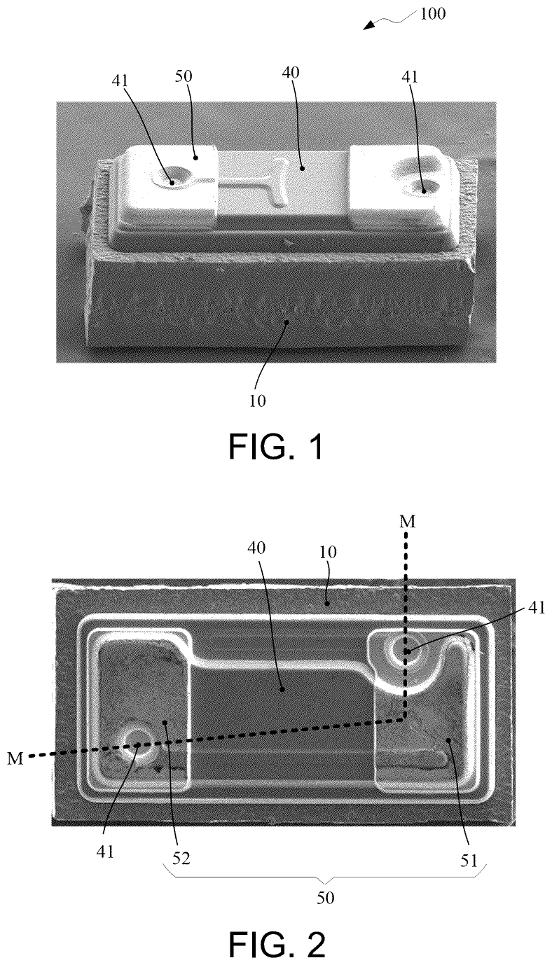

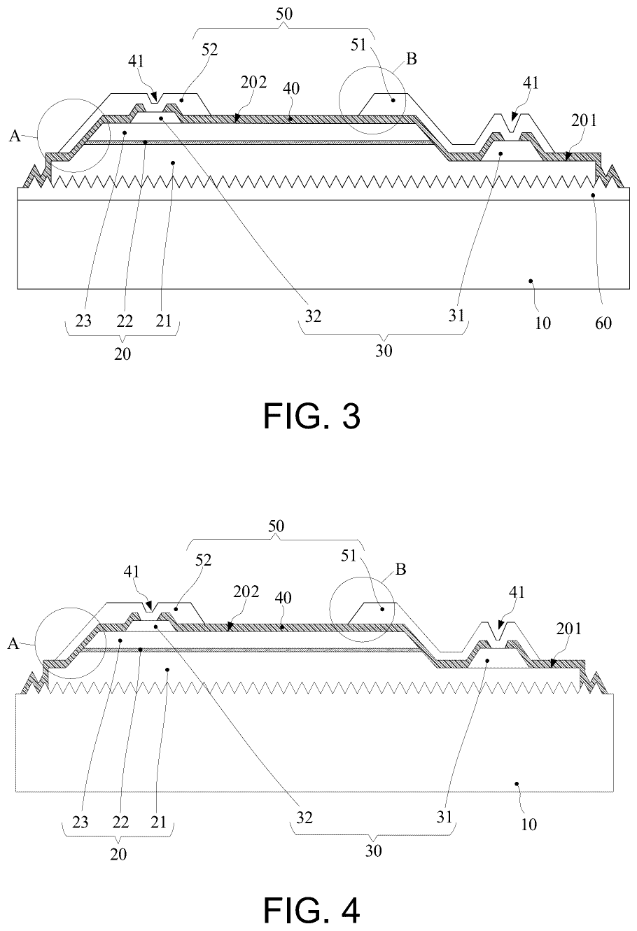

As shown in FIG. 1, FIG. 2, FIG. 3 and FIG. 4, this embodiment provides a flip-chip light-emitting element 100, which at least includes an epitaxial layer 20, a contact electrode 30, an insulating layer 40 and a pad electrode 50. The epitaxial layer 20 includes a first semiconductor layer 21, an active layer 22 and a second semiconductor layer 23 stacked in sequence. The first semiconductor layer 21 forms a first mesa 201. The first semiconductor layer 21, the active layer 22 and the second semiconductor layer 23 form a second mesa 202 that is higher than the first mesa 201. For example, the epitaxial layer 20 is a gallium nitride-based or aluminium gallium indium phosphorus-based epitaxial layer, and the first semiconductor layer 21 is n-type doped gallium nitride or aluminium gallium indium phosphorus, for example, n-type gallium nitride or aluminium gallium indium phosphorus doped with Si, Ge, or Sn. The second semiconductor layer 23 is p-type doped gallium nitride or aluminium gallium indium phosphorus, for example, p-type gallium nitride or aluminium gallium indium phosphorus doped with Mg, Zn, Ca, Sr, or Ba. The active layer 22 is a material that may provide light radiation, and the active layer 22 may be a semiconductor material using a gallium arsenide (GaAs) series. Specifically, when the active layer 22 adopts semiconductor materials of the aluminium indium gallium phosphide (AlGaInP) series or the gallium arsenide (GaAs) series, the active layer 22 may emit red light, orange light or yellow light. When the semiconductor materials of the aluminium gallium indium nitride (AlGaInN) series are adopted, the active layer 22 may emit blue or green light. The active layer 22 may include at least one un-doped semiconductor layer or at least one low-doped layer. The active layer 22 may be a singleheterostructure (SH), a doubleheterostructure (DH), a double-sideddoubleheterostructure (DDH), or a multi-quantumwell (MQW) structure, but this embodiment is not limited thereto.

As shown in FIG. 3, the flip-chip light-emitting element 100 may include a substrate 10 and a bonding layer 60, and the epitaxial layer 20 may be bonded to the substrate 10 through the bonding layer 60. For example, when the active layer 22 of the epitaxial layer 20 adopts the semiconductor materials of the gallium arsenide (GaAs) series, the active layer 22 may emit red light. Specifically, the epitaxial layer 20 is grown on the gallium arsenide substrate, and then the grown epitaxial layer 20 is flipped and bonded to the transparent sapphire substrate 10 through the bonding layer 60. Thereafter, the gallium arsenide substrate is removed, and the contact electrode 30, the insulating layer 40, the pad electrode 50, and so on are formed on the epitaxial layer 20 subsequently.

The material of the bonding layer 60 may be an insulating material and/or a conductive material. Insulating materials include but are not limited to polyimide (PI), benzocyclobutene (BCB), perfluorocyclobutane (PFCB), magnesium oxide (MgO), Su8, epoxy, acrylic resin, cycloolefin polymer (COP), polymethyl methacrylate (PMMA), polyethylene terephthalate (PET), polycarbonate (PC), polyetherimide, fluorocarbon polymer, glass, aluminium oxide (Al₂O₃), silicon oxide (SiOx), titanium oxide (TiO₂), tantalum oxide (Ta₂O₅), silicon nitride (SiNx) or spin-on glass (SOG). Conductive materials include but are not limited to indium tin oxide (ITO), indium oxide (InO), tin oxide (SnO), cadmium tin oxide (CTO), antimony tin oxide (ATO), aluminium zinc oxide (AZO), zinc tin oxide (ZTO), zinc oxide (ZnO), indium zinc oxide (IZO), diamond-like carbon layer (DLC) or gallium zinc oxide (GZO), etc. When the bonding layer 60 adopts a conductive material to contact the first semiconductor layer 21 of the epitaxial layer 20, the bonding layer 60 may serve as a current spreading layer, thus improving the current spreading effect, and enhancing the uniformity of current distribution.

As shown in FIG. 4, the flip-chip light-emitting element 100 may include the substrate 10 and not include the bonding layer 60. The epitaxial layer 20 is grown directly on the substrate 10. For example, when the active layer 22 of the epitaxial layer 20 adopts the semiconductor materials of aluminium gallium indium nitride (AlGaInN) series, the active layer 22 may emit blue light or green light. Under the circumstances, the epitaxial layer 20 may be directly grown on the sapphire substrate 10. After the epitaxial layer 20 is grown, the contact electrode 30, the insulating layer 40, the pad electrode 50, and so on are formed on the epitaxial layer 20.

The contact electrode 30 is formed on the surfaces of the first mesa 201 and the second mesa 202 of the epitaxial layer 20. Specifically, the contact electrode 30 includes a first electrode structure 31 and a second electrode structure 32. The first electrode structure 31 is formed on the first semiconductor layer 21 and is electrically connected to the first semiconductor layer 21. The second electrode structure 32 is formed on the second semiconductor layer 23 and electrically connected with the second semiconductor layer 23.

The insulating layer 40 is formed on the epitaxial layer 20 and at least covers the surface, the edge area and the sidewall of the epitaxial layer 20. The conductive via 41 is disposed on the insulating layer 40 corresponding to the first electrode structure 31 and the second electrode structure 32. The material of the insulating layer 40 may include at least two of different materials including SiO₂, TiO₂, ZnO₂, ZrO₂, Cu₂O₃, etc., and the insulating layer 40 may include a distributed Bragg reflector, wherein the distributed Bragg reflector is formed by using, for example, an electron beam evaporation or an ion beam sputtering technology and so on to alternately stack two materials into multiple layers.

The pad electrode 50 is formed on the insulating layer 40 and connected to the contact electrode 30, and the pad electrode 50 at least covers part of the sidewall of the epitaxial layer 20. The pad electrode 50 includes a first pad electrode 51 and a second pad electrode 52. The first pad electrode 51 is electrically connected to the first electrode structure 31 through the conductive via 41 above the first electrode structure 31. The second pad electrode 50 is electrically connected to the second electrode structure 32 through the conductive via 41 above the second electrode structure 32.

In this embodiment, since the pad electrode 50 at least covers part of the sidewall of the epitaxial layer 20. During the solder paste solidification process, even if Sn and Ag migrate and ascend, they will first migrate and ascend along the sidewall of the pad electrode 50. Due to the blocking effect of the pad electrode 50 at the sidewall and the limited height that Sn and Ag can reach through migration and ascending, it is difficult for migrated and ascended Sn and Ag to enter the active layer 22 of the epitaxial layer 20. In this way, it is possible to reduce the possibility of leakage failure of flip-chip light-emitting elements 100 and improve the reliability of flip-chip light-emitting elements 100. Even if some Sn and Ag migrate and ascend beyond the height of the sidewall covered by the pad electrode 50, the height that Sn and Ag can reach is relatively low. In addition, the insulating layer 40 may also block a small amount of Sn and Ag, thereby preventing the migrated and ascended Sn and Ag from entering the active layer 22.

In addition, since the pad electrode 50 at least covers part of the sidewall of the epitaxial layer 20, the contact area between the pad electrode 50 and the solder paste is increased, thereby improving the solderability of the flip-chip light-emitting element 100.

In this embodiment, the spacing between the first pad electrode 51 and the second pad electrode 52 may account for 10% to 80% of the dimension of the long side of the epitaxial layer 20. In order to design the spacing between the first pad electrode 51 and the second pad electrode 52 to be preferable for the soldering process, as well as to reduce the risk of short circuit, and improve the solderability, it is preferable that the spacing between the first pad electrode 51 and the second pad electrode 52 accounts for 20% to 40% of the dimension of the long side of the epitaxial layer 20.

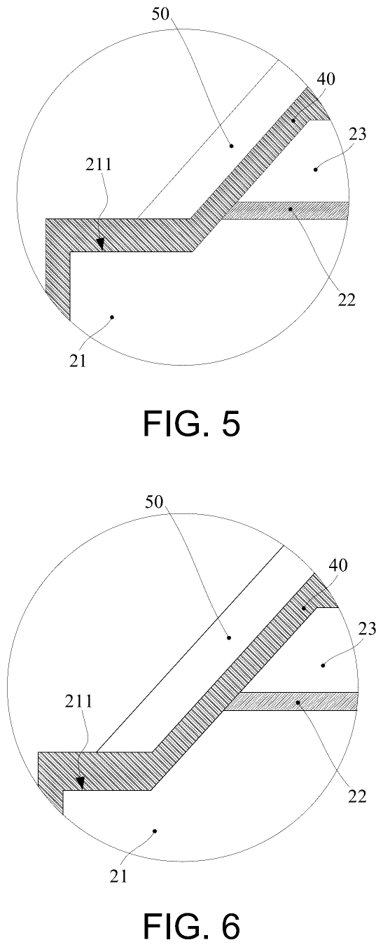

In this embodiment, at the sidewall of the epitaxial layer 20, the pad electrode 50 at least covers the active layer 22. As shown in FIG. 5, the pad electrode 50 covers the sidewall of the active layer 22. As shown in FIG. 6, the pad electrode 50 completely covers the sidewall of the active layer 22 and extends downward for a certain distance. After the pad electrode 50 covers the sidewall of the active layer 22, even if Sn and Ag migrate and ascend to the sidewall of the active layer 22 during the solder paste solidification process, the pad electrode 50 may effectively block Sn and Ag.

In this embodiment, as shown in FIG. 5 and FIG. 6, a semiconductor step surface 211 may be disposed on the sidewall of the first semiconductor layer 21, and the sidewall above the semiconductor step surface 211 is aligned with the sidewall of the second semiconductor layer 23 and the sidewall of the active layer 22, and the sidewalls of the first semiconductor layer 21, the second semiconductor layer 23 and the active layer 22 have the same predetermined inclined angle. The setting of the inclined angle of the sidewalls facilitates the formation of the insulating layer 40 and the pad electrode 50.

The pad electrode 50 may have a single-layer structure or a multi-layer structure. In this embodiment, the pad electrode 50 may have a single-layer structure and is made of a metal material, specifically any combination of Au, Ti, Al, Cr, Pt, TiW alloy or Ni.

It should be noted that although the inclined sidewalls facilitate the formation of the insulating layer 40, the insulating layer 40 is likely to have gaps when the inclined sidewalls are formed, which might cause other elements to enter the sidewall of the epitaxial layer 20. The pad electrode 50 covering the sidewall of the active layer 22 may also substantially cover the gap at the inclined sidewall of the insulating layer 40, thereby preventing other elements from entering during soldering as much as possible.

In this embodiment, as shown in FIG. 5 and FIG. 6, in order for the pad electrode 50 to cover the sidewall of the active layer 22, the height of the portion of the insulating layer 40 formed on the semiconductor step surface 211 does not exceed the upper surface of the first semiconductor layer 21, and the coverage of pad electrode 50 reaches the insulating layer 40 on the semiconductor step surface 211.

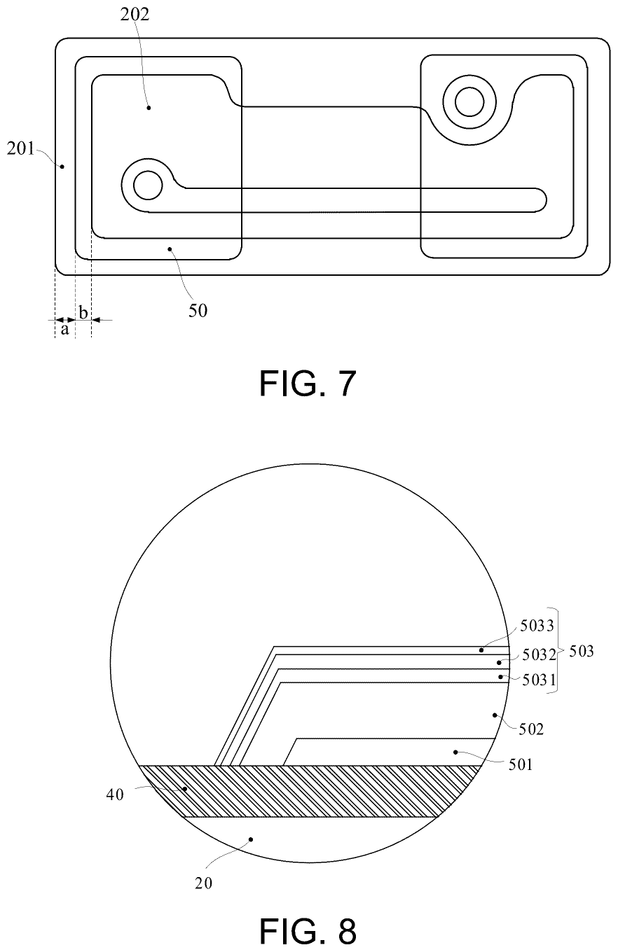

In this embodiment, as shown in FIG. 5 and FIG. 6, the boundary of the pad electrode 50 does not exceed the boundary of the semiconductor step surface 211. Preferably, the boundary of the pad electrode 50 does not exceed and does not overlap the boundary of the semiconductor step surface 211. For example, as shown in FIG. 7, when the boundary of the pad electrode 50 does not exceed and does not overlap the boundary of the semiconductor step surface 211, the distance between the boundary of the pad electrode 50 and the boundary of the first mesa 201 is a>1 um, and the distance between the boundary of the pad electrode 50 and the boundary of the second mesa 202 is b>1 um.

### Embodiment 2

This embodiment further provides a flip-chip light-emitting chip. The similarities between this embodiment and Embodiment 1 will not be described again here.

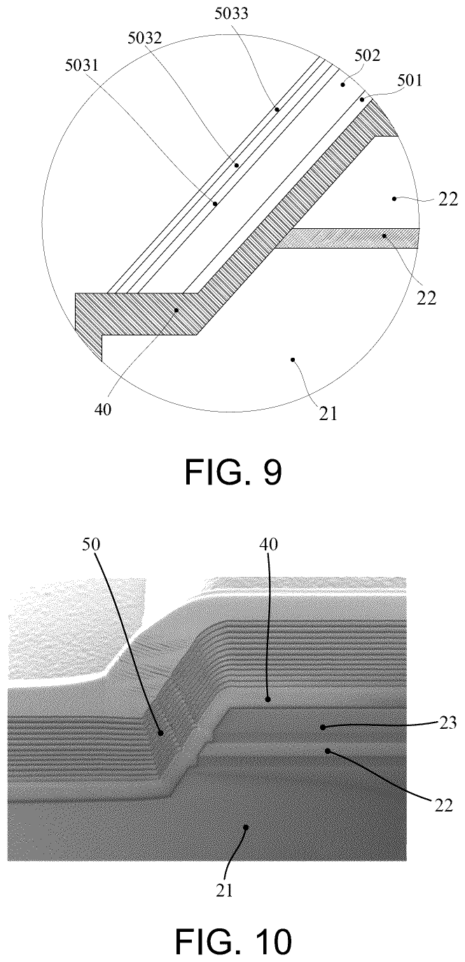

The difference between Embodiment 2 and Embodiment 1 is that, as shown in FIG. 8 and FIG. 9, in this embodiment, the pad electrode 50 has a multi-layer structure, such as a stacked structure. The stacked structure includes a first layer structure 501, an intermediate layer structure 502 and a final layer structure 503 stacked in sequence. The first layer structure 501 is formed on the insulating layer 40, the intermediate layer structure 502 is formed on the surface of the first layer structure 501, and the final layer structure 503 is formed on the surface of the intermediate layer structure 502.

FIG. 10 shows a partial cross-sectional view of the flip-chip light-emitting element of this embodiment observed using an electron microscope, a gap is present on the insulating layer 40 formed at the inclined sidewall of the epitaxial layer 20. However, referring to FIG. 8, FIG. 9 together with FIG. 10, the first layer structure 501 in the pad electrode 50 formed after the insulating layer 40 is formed may block the gap on the insulating layer 40, the subsequently formed intermediate layer structure 502 may further block the gap on the first layer structure 501, and the finally formed final layer structure 503 may block the gap on the intermediate layer structure 502. It can be seen that by stacking the pad electrode 50 in a layer-by-layer manner, the subsequently formed layers may block the gaps on the previously formed layers, thereby effectively blocking the migrated and ascended Sn and Ag.

In this embodiment, the first layer structure 501 is a Ti layer or a Cr layer or an alloy layer of Ti and Cr. In this way, on the one hand, the first layer structure 501 may block the mutual diffusion of metals between the pad electrode 50 and the contact electrode 30. On the other hand, there is good contact adhesion between the Ti layer or Cr layer or the alloy layer of Ti and Cr and the insulating layer 40, thereby improving the reliability of the pad electrode 50. The thickness of the first layer structure 501 may be 20 Å to 1000 Å, and the preferred thickness is 20 Å to 500 Å.

In this embodiment, as shown in FIG. 8 and FIG. 9, the final layer structure 503 may include a barrier layer 5031 that is a Ti layer. The barrier layer 5031 which is a Ti layer enables the final layer structure 503 to have a better blocking effect, thereby effectively blocking corrosive elements in the solder paste from entering the pad electrode 50 and corroding the metal in the pad electrode 50. The thickness of the barrier layer 5031 may be 300 Å to 3000 Å, such as 300 Å, 500 Å, 800 Å, 1000 Å, 1500 Å, 2000 Å, 2500 Å, 3000 Å, etc.

In this embodiment, as shown in FIG. 8 and FIG. 9, the final layer structure 503 further includes a transition layer 5032 formed on the barrier layer 5031 and a wetting layer 5033 formed on the transition layer 5032; the transition layer 5032 may be a Ni layer or a Pt layer and a Ni layer stacked in sequence; the wetting layer 5033 is an Au layer or Sn layer. The thickness of the transition layer 5032 may be 500 Å to 8000 Å, such as 500 Å, 800 Å, 1000 Å, 2000 Å, 3000 Å, 4000 Å, 5000 Å, 6000 Å, 7000 Å, 8000 Å, etc. The thickness of the wetting layer 5033 may range from 300 Å to 3000 Å, such as 300 Å, 500 Å, 800 Å, 1000 Å, 1500 Å, 2000 Å, 2500 Å, 3000 Å, etc.

For example, the final layer structure 503 may be a Ti layer, a Ni layer, and an Au layer stacked in sequence, or a Ti layer, a Pt layer, a Ni layer, and an Au layer stacked in sequence, or a Ti layer, a Pt layer, a Ni layer, and an Sn layer stacked in sequence.

It should be noted that the intermediate layer structure 502 of the pad electrode 50 may be a single-layer structure or a double-layer structure. In this embodiment, the intermediate layer structure 502 may adopt a single-layer structure.

In this embodiment, the pad electrode 50 of the flip-chip light-emitting element is designed into a stacked structure, and the pad electrode 50 covers the sidewall of the epitaxial layer 20. Because the first layer structure 501 in the stacked structure of the pad electrode 50 is a Ti layer, the barrier layer 5031 of the final layer structure 503 is a Ti layer, and the transition layer 5032 of the final layer structure 503 may also include a Ti layer, the stacked structure of the pad electrode 50 forms a multi-layer barrier layer, which may effectively block Sn and Ag from migrating to the active layer 22 at the sidewall of the chip during the solder paste solidification process, thereby significantly reducing the probability of leakage failure and abnormality of the flip-chip light-emitting element.

Moreover, in this embodiment, the first layer structure 501 and the final layer structure 503 of the pad electrode 50 are both provided with a barrier layer formed by a Ti layer, which may block solder paste migration and ohmic contact electrode reaction, thereby improving the reliability of the flip-chip light-emitting element.

In this embodiment, as shown in FIG. 8 and FIG. 9, the intermediate layer structure 502 completely covers the first layer structure 501, and the final layer structure 503 completely covers the intermediate layer structure 502. Further, the barrier layer 5031 of the final layer structure 503 completely covers the intermediate layer structure 502, the transition layer 5032 of the final layer structure 503 completely covers the barrier layer 5031, and the wetting layer 5033 of the final layer structure 503 completely covers the transition layer 5032. The layer-by-layer covering structure prevents corrosive elements from entering the pad electrode 50 and corroding the metal in the pad electrode 50 as much as possible, and also helps to improve the reliability of flip-chip light-emitting elements.

### Embodiment 3

Similarly, this embodiment provides a flip-chip light-emitting chip. The similarities between this embodiment and Embodiment 2 will not be described again here.

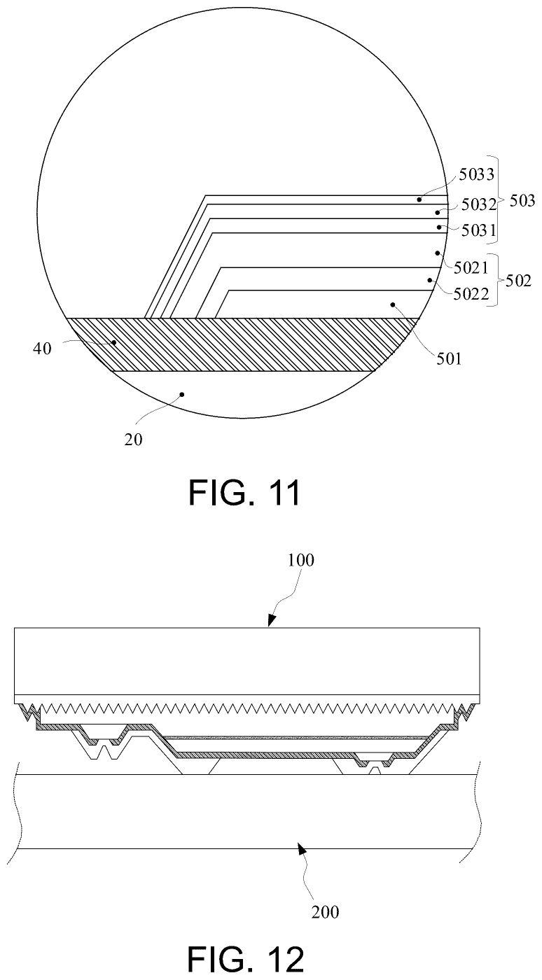

The difference between Embodiment 3 and Embodiment 2 is that, as shown in FIG. 11, in this embodiment, the intermediate layer structure 502 is a multi-layer structure.

Specifically, the intermediate layer structure 502 includes an initial layer 5021 and a combined layer 5022 stacked in sequence. The initial layer 5021 may be an Al layer, and the combined layer 5022 includes at least a group of Ti layers and Al layers stacked in sequence. For example, the intermediate layer structure 502 may be a combination of four groups of overlapping Ti layers and Al layers stacked on top of an Al layer, which may be simply expressed as Al/(Ti/Al)*4, then the corresponding stacked structure of the pad electrode 50 may be simply expressed as Ti/Al/(Ti/Al)*4/Ti/Ni/Au from the innermost to the outermost material layer.

The initial layer 5021 may also be a Pt material layer, the combined layer 5022 includes at least one group of Ti material layers and Pt material layers that are stacked in sequence, and the intermediate layer structure 502 may be a combination of two groups of overlapping Ti layers and Pt layers stacked on top of a Pt layer, which may be simply expressed as Pt/(Ti/Pt)*2, then the corresponding stacked structure of the pad electrode 50 may be simply expressed as Ti/Pt/(Ti/Pt)*2/Ti/Ni/Au from the innermost to the outermost material layer.

In this embodiment, as shown in FIG. 11, the initial layer 5021 of the intermediate layer structure 502 completely covers the first layer structure 501, and the combined layer 5022 of the intermediate layer structure 502 completely covers the initial layer 5021.

### Embodiment 4

This embodiment provides a light-emitting device, as shown in FIG. 12, including a substrate 200 and any flip-chip light-emitting element 100 in Embodiment 1 to Embodiment 3. The flip-chip light-emitting element 100 is soldered on the substrate 200.

The above are only preferred embodiments of the present disclosure and are not intended to limit the present disclosure. For those skilled in the art, the present disclosure may be modified and changed in various ways. Any modifications, equivalent replacements, improvements, etc. made within the spirit and principles of this disclosure shall be included in the scope to be protected by the disclosure.

What is claimed is:

1. A flip-chip light-emitting element, at least comprising:
an epitaxial layer comprising a first semiconductor layer, an active layer and a second semiconductor layer stacked in sequence;
a contact electrode formed on a surface of the epitaxial layer;
an insulating layer formed on the epitaxial layer, and at least covering the surface of the epitaxial layer, an edge area of the epitaxial layer and a sidewall of the epitaxial layer;
a pad electrode formed on the insulating layer and connected to the contact electrode, and the pad electrode covering at least a part of the sidewall of the epitaxial layer.

2. The flip-chip light-emitting element according to claim 1, wherein at the sidewall of the epitaxial layer, the pad electrode at least covers the active layer.

3. The flip-chip light-emitting element according to claim 2, wherein a semiconductor step surface is disposed on a sidewall of the first semiconductor layer, and the sidewall of the first semiconductor layer above the semiconductor step surface is aligned with a sidewall of the second semiconductor layer and a sidewall of the active layer, and the sidewalls of the first semiconductor layer, the second semiconductor layer and the active layer have a same predetermined inclined angle.

4. The flip-chip light-emitting element according to claim 3, wherein a height of a portion of the insulating layer formed on the semiconductor step surface does not exceed an upper surface of the first semiconductor layer, and a coverage of the pad electrode reaches the insulating layer on the semiconductor step surface.

5. The flip-chip light-emitting element according to claim 4, wherein a projection of a boundary of the pad electrode on the semiconductor step surface does not exceed a boundary of the semiconductor step surface.

6. The flip-chip light-emitting element according to claim 5, wherein the projection of the boundary of the pad electrode on the semiconductor step surface does not overlap the boundary of the semiconductor step surface.

7. The flip-chip light-emitting element according to claim 1, wherein pad electrode is a stacked structure, and the stacked structure comprises a first layer structure, an intermediate layer structure and a final layer structure stacked in sequence;
wherein the first layer structure is formed on the insulating layer, the intermediate layer structure is formed on a surface of the first layer structure, and the final layer structure is formed on a surface of the intermediate layer structure.

8. The flip-chip light-emitting element according to claim 7, wherein the first layer structure is a Ti layer or a Cr layer or an alloy layer of Ti and Cr.

9. The flip-chip light-emitting element according to claim 8, wherein the final layer structure comprises a barrier layer that is a Ti layer.

10. The flip-chip light-emitting element according to claim 9, wherein the final layer structure further comprises a transition layer formed on the barrier layer and a wetting layer formed on the transition layer, the transition layer is a Ni layer or a Pt layer and a Ni layer stacked in sequence; the wetting layer is an Au layer or Sn layer.

11. The flip-chip light-emitting element according to claim 7, wherein the intermediate layer structure is a single-layer structure or a multi-layer structure.

12. The flip-chip light-emitting element according to claim 7, wherein the intermediate layer structure completely covers the first layer structure, and the final layer structure completely covers the intermediate layer structure.

13. The flip-chip light-emitting element according to claim 1, wherein a conductive via is disposed on the insulating layer, the pad electrode is electrically connected to the contact electrode through the conductive via, and the pad electrode completely covers the conductive via.

14. The flip-chip light-emitting element according to claim 1, wherein the contact electrode comprises a first electrode structure and a second electrode structure, the first electrode structure is formed on the first semiconductor layer and is electrically connected to the first semiconductor layer, the second electrode structure is formed on the second semiconductor layer and electrically connected to the second semiconductor layer;
the pad electrode comprises a first pad electrode and a second pad electrode, the first pad electrode is electrically connected to the first electrode structure, and the second pad electrode is electrically connected to the second electrode structure.

15. The flip-chip light-emitting element according to claim 14, wherein a spacing between the first pad electrode and the second pad electrode accounts for 10% to 80% of a dimension of a long side of the epitaxial layer.

16. The flip-chip light-emitting element according to claim 1, wherein the flip-chip light-emitting element further comprises a substrate and a bonding layer, and the epitaxial layer is bonded to the substrate through the bonding layer.

17. A light-emitting device, comprising the flip-chip light-emitting element according to claim 1.
